(19) United States
(12) Patent Application Publication
(10) Pub. No.: US 2003/0112043 A1
(43) Pub. Date: Jun. 19, 2003

(54) PLL circuit and control method for PLL circuit

(75) Inventor: Masayuki Takahashi, Hamamatu-shi (JP)

Correspondence Address: OLIFF & BERRIDGE, PLC, P.O. BOX 19928, ALEXANDRIA, VA, 22320, US

(73) Assignee: Ando Electric Co., Ltd., Tokyo (JP)

(21) Appl. No.: 10/298,822

(22) Filed: Nov. 19, 2002

(30) Foreign Application Priority Data
Dec. 19, 2001 (JP) 2001-386220

(51) Int. Cl. H03L 7/06

(52) U.S. Cl. 327/156

(57) ABSTRACT

A PLL circuit for reducing an error in a frequency of an output signal for a reference signal and outputting the output signal with a smaller spurious output, and a control method for the PLL circuit. The PLL circuit has: a clock generator for generating and outputting a clock signal having an oscillating frequency, on the basis of a reference input signal; a phase detector for detecting a phase difference between the clock signal and an output feedback signal, and outputting a phase difference signal; a controller for controlling an oscillating frequency of an output signal on the basis of the phase difference signal; and a divider for dividing the oscillating frequency of the output signal outputted from the controller, and outputting a dividing signal having an oscillating frequency corresponding to the oscillating frequency of the clock signal, as the output feedback signal.

### BACKGROUND OF THE INVENTION

1. Field of the Invention

The present invention relates to a PLL (Phase Lock Loop) circuit using a DDS (Direct Digital Synthesizer), and a control method for the PLL circuit.

2. Description of Related Art

Conventionally, a PLL (Phase Lock Loop) circuit is used for a transmission apparatus corresponding to a high speed digital communication system, a measurement apparatus for evaluating a transmission quality of transmission system such as a main network, or the like. The PLL circuit divides a frequency of a signal outputted from a VCO (Voltage Controlled Oscillator), and controls the signal so that the divided frequency and a phase of the signal coincide with a reference frequency and a phase of a reference frequency signal having the reference frequency, respectively. Therefore, the VCO outputs an oscillating signal having a desired frequency.

FIG. 2 is a block diagram showing a structure of a PLL circuit 10 comprising a DDS (Direct Digital Synthesizer) according to an earlier development. As shown in FIG. 2, the PLL circuit 10 comprises a DDS 11, a PD (Phase Detector) 12, a VCO 13 and a frequency divider 14.

The DDS 11 cumulatively adds a phase angle which is determined optionally, in synchronism with a reference frequency signal inputted thereto. Thereby, the DDS 11 generates a discrete waveform of a desired frequency, and outputs a phase reference signal to the PD 12.

The PD 12 detects a phase difference between the phase reference signal outputted from the DDS 11 and a dividing signal fed back from the following frequency divider 14. Then, the PD 12 outputs a phase difference signal having a pulse wide corresponding to the phase difference, to the VCO 13.

The VCO 13 generally detects the phase difference signal outputted from the PD 12, and changes an oscillating frequency of an output signal according to a voltage change of the detected signal. Then, the VCO 13 outputs the signal having the desired output frequency.

The frequency divider 14 divides the frequency of the signal outputted from the VCO 13 by N (“N” is an integer.), and outputs the dividing signal to the PD 12.

That is, because the VCO 13 also outputs the output signal to the frequency divider 14, and the frequency divider 14 feeds back the dividing signal having the frequency divided by N to the PD 12, the PLL circuit 10 has a structure so as to always control the phase change and maintain the constant frequency of the output signal.

Next, the behavior of the PLL circuit 10 will be explained. When the DDS 11 receives the reference frequency signal having the frequency (fo), the DDS 11 samples the reference frequency signal for every frequency which is optionally determined, and outputs the phase reference signal having the frequency (fr) to the PD 12.

On the other hand, when the frequency divider 14 receives the output signal outputted from the VCO 13, the frequency divider 14 divides the frequency of the output signal by the dividing value (N) (“IN” is an integer.), and outputs the dividing signal to the PD 12.

Then, the PD 12 compares the phase of the phase reference signal outputted from the DDS 11 with the phase of the dividing signal outputted from the frequency divider 14, and outputs the phase difference signal of the pulse wide according to the phase difference to the VCO 13. Accordingly, the VCO 13 controls the phase change on the basis of the phase difference signal, and outputs the output signal having the constant frequency (fv).

Next, the frequency relationship between the reference frequency signal having the frequency (fo) and the output signal having the frequency (fv) of the PLL circuit 10 is shown in the following equation [2].

fo×D/2^{k}=fv/N, fv=fo×D/2^{k}×N [2]

Herein, “fo” is the frequency of the reference frequency signal, “fv” is the frequency of the output signal, “N” is the dividing value of the frequency divider 14, “D” is the frequency setting value of the DDS 11, and “k” is the bit number of the setting resolution of the DDS 11.

The setting value D is calculated by substituting the specific values for the above-described equation [2]. For example, in order to output the output signal having the 101 Hz frequency (fv=101 Hz) on the basis of the reference frequency signal having the 10 Hz frequency (fo=10 Hz), the frequency setting value (D) is set as follows.

101/N=10×(D/2^{k}), D=(101/10)×2^{k}/N

From the property of the DDS 11, the frequency setting value (D) is smaller than 2^{k-1} (D<2^{k-1}), and the dividing value (N) is an integer. Therefore, in order to make the frequency (fr) of the phase reference signal higher (for example, fr=4 Hz), when the dividing value (N) is about 25 (≈101/4), the frequency setting value (D) is determined as follows.

D=(101/10)×2^{k}/25

However, because the frequency setting value (D) of the DDS 11 is required to be an integer in the PLL circuit 10 according to an earlier development, the integral frequency setting value (D) always causes an error in the frequency (fv) of the output signal.

As a result, for example, in case of synchronizing a high speed transmission signal (for example, 10 GHz band) with a low speed reference frequency signal (for example, 1.544 MHz) such as the SDH (Synchronous Digital Hierarchy), a few error in the frequency causes an error in the bit. More specifically, even if the reference frequency signal and the output signal have the synchronous relationship, when the error in the frequency is +0.1 ppm, it occurs that 10⁷+1 bit data are transmitted while 10⁷ bit data are usually transmitted.

Further, according to the setting value of the DDS 11, a spurious output having an unnecessary frequency other than the desired frequency is generated in the output signal outputted from the DDS 11, by a non-linear property, a quantum error or the like of a D/A converter incorporated in the DDS 11. Although it is possible to avoid generating the spurious output by changing the setting value of the DDS 11, one setting value of the DDS 11 is determined so as to correspond to the frequency of the output signal according to the relationship shown in the above-described equation [2]. Therefore, in case the spurious output is generated according to one setting value of the DDS 11, when the setting value of the DDS 11 is changed to avoid generating the spurious output, the error is caused in the frequency of the output signal.

As a means for avoid generating the spurious output, for example, there is a method for selecting any one of a plurality of reference frequencies, and thereby avoiding generating the spurious output, as a DDS disclosed in Japanese Utility Model Application (Laid-open) No. Jitsugan-hei 3-47134. However, the plurality of reference frequencies causes expanding the size of the circuit, and are disadvantage in the cost.

### SUMMARY OF THE INVENTION

The present invention was developed in view of the above-described problems.

It is an object of the present invention to provide a PLL circuit for reducing an error in a frequency of an output signal for a reference signal and outputting the output signal with a smaller spurious output, and a control method for the PLL circuit.

In accordance with a first aspect of the present invention, a PLL circuit (for example, a PLL circuit 1 shown in FIG. 1) comprises: a clock generator (for example, a DDS 11a shown in FIG. 1) for generating and outputting a clock signal having an oscillating frequency, on the basis of a reference input signal; a phase detector (for example, a PD 12 shown in FIG. 1) for detecting a phase difference between the clock signal outputted from the clock generator and an output feedback signal, and outputting a phase difference signal; a controller (for example, a VCO 13 shown in FIG. 1) for controlling an oscillating frequency of an output signal on the basis of the phase difference signal outputted from the phase detector; and a divider (for example, a DDS 11b shown in FIG. 1) for dividing the oscillating frequency of the output signal outputted from the controller, and outputting a dividing signal having an oscillating frequency corresponding to the oscillating frequency of the clock signal, as the output feedback signal.

According to the PLL circuit of the first aspect of the present invention, the clock generator generates and outputs a clock signal having an oscillating frequency, on the basis of a reference input signal, the phase detector detects a phase difference between the clock signal outputted from the clock generator and an output feedback signal, and outputs a phase difference signal, the controller controls an oscillating frequency of an output signal on the basis of the phase difference signal outputted from the phase detector, and the divider divides the oscillating frequency of the output signal outputted from the controller, and outputs a dividing signal having an oscillating frequency corresponding to the oscillating frequency of the clock signal, as the output feedback signal. Consequently, even if each of an oscillating frequency setting value set by the clock generator and an oscillating frequency setting value set by the divider is an integer, in case a ratio of the oscillating frequency setting value set by the clock generator to the oscillating frequency setting value set by the divider coincides with a ratio of an oscillating frequency of the reference input signal to the oscillating frequency of the output signal, it is possible that the controller outputs the output signal having the correct frequency without a frequency error.

Preferably, in the PLL circuit of the first aspect of the present invention, each of the clock generator and the divider comprises a direct digital synthesizer for generating a signal corresponding to an optional oscillating frequency.

According to the PLL circuit, because each of the clock generator and the divider comprises a direct digital synthesizer for generating a signal corresponding to an optional oscillating frequency, it is possible to optionally change the oscillating frequency of the output signal outputted from the controller by changing an oscillating frequency setting value set by the clock generator and an oscillating frequency setting value set by the divider. Further, it is possible to set the more accurate oscillating frequency according to the high resolution of the direct digital synthesizer.

Preferably, in the PLL circuit of the first aspect of the present invention, a relationship between a ratio of an oscillating frequency (fo) of the reference input signal inputted to the clock generator to the oscillating frequency (fv) of the output signal outputted from the controller, and a ratio of an oscillating frequency setting value (Da) set by the clock generator to an oscillating frequency setting value (Db) set by the divider, is shown in the following equation [1]:

fv/fo=Da/Db [1].

According to the PLL circuit, because the relationship between the ratio of the oscillating frequency of the reference input signal inputted to the clock generator to the oscillating frequency of the output signal outputted from the controller, and the ratio of the oscillating frequency setting value set by the clock generator to the oscillating frequency setting value set by the divider, is shown in the above-described equation [1], it is possible to optionally select a combination of the oscillating frequency setting values (Da) and (Db) for the frequency (fv) of the output signal. Consequently, it is possible to avoid generating a spurious output by changing the setting values (Da) and (Db), without expanding a size of the circuit, and causing a frequency error in the output signal.

Preferably, in the PLL circuit as described above, the oscillating frequency setting values of the clock generator and the divider are changed with keeping the relationship shown in the equation [1], the clock generator and the divider each of which comprises a direct digital synthesizer for generating a signal corresponding to an optional oscillating frequency, when a spurious output is generated in the output signal.

According to the PLL circuit, because the oscillating frequency setting values of the clock generator and the divider each of which comprises the direct digital synthesizer, are changed with keeping the relationship shown in the equation [1], when a spurious output is generated in the output signal, it is possible to avoid generating a spurious output without changing the oscillating frequency of the output signal.

In accordance with a second aspect of the present invention, a control method for a PLL circuit comprises: generating and outputting a clock signal having an oscillating frequency, on the basis of a reference input signal; detecting a phase difference between the clock signal outputted and an output feedback signal, and outputting a phase difference signal; controlling an oscillating frequency of an output signal on the basis of the phase difference signal outputted; and dividing the oscillating frequency of the output signal outputted, and outputting a dividing signal having an oscillating frequency corresponding to the oscillating frequency of the clock signal, as the output feedback signal.

Preferably, in the control method of the second aspect of the present invention, the generating and outputting a clock signal is accomplished by a first direct digital synthesizer for generating a signal corresponding to an optional oscillating frequency, and the dividing the oscillating frequency of the output signal outputted, and outputting a dividing signal is accomplished by a second direct digital synthesizer for generating a signal corresponding to an optional oscillating frequency.

Preferably, the control method as described above, further comprises: changing an oscillating frequency setting value (Da) set by the first direct digital synthesizer and an oscillating frequency setting value (Db) set by the second direct digital synthesizer with keeping a relationship between a ratio of an oscillating frequency (fo) of the reference input signal to the oscillating frequency (fv) of the output signal and a ratio of the oscillating frequency setting value (Da) to the oscillating frequency setting value (Db), shown in the following equation, when a spurious output is generated in the output signal:

fv/fo =Da/Db.

### BRIEF DESCRIPTION OF THE DRAWINGS

The present invention will become more fully understood from the detailed description given hereinafter and the accompanying drawing given by way of illustration only, and thus are not intended as a definition of the limits of the present invention, and wherein:

FIG. 1 is a block diagram showing a structure of a PLL circuit 1 according to an embodiment of the present invention; and

FIG. 2 is a block diagram showing the structure of the PLL circuit 10 according to an earlier development.

### PREFERRED EMBODIMENTS OF THE INVENTION

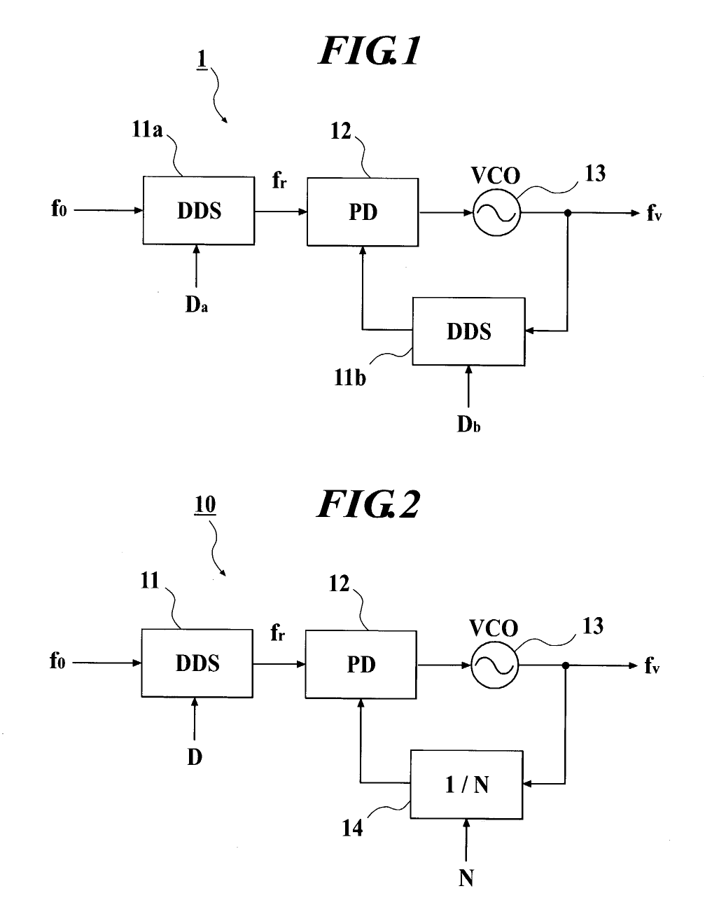

Hereinafter, a preferred embodiment of the present invention will be explained with reference to FIG. 1, in detail.

FIG. 1 is a block diagram showing an embodiment of a PLL circuit 1 to which the present invention is applied.

First, a structure of the PLL circuit 1 will be explained. The same reference numerals are attached to the same elements of the PLL circuit 1 as the elements of the PLL circuit 10 according to an earlier development, shown in FIG. 2, and the same elements of the PLL circuit 1 will be omitted explaining.

As shown in FIG. 1, the PLL circuit 1 comprises two DDSs 11a and 11b, the PD 12, and the VCO 13.

The PLL circuit 1 shown in FIG. 1, according to an embodiment of the present invention, is different from the PLL circuit 10 shown in FIG. 2, according to an earlier development, in comprising the DDS 11b instead of the frequency divider 14. That is, the DDS 11b divides the frequency of the signal outputted from the VCO 13 by an optional setting value, and outputs a dividing signal to the PD 12.

The relationship between the frequency (fo) of the reference frequency signal and the frequency (fv) of the output signal in the PLL circuit 1 according to an earlier development of the present invention, will be shown in the following equation [1].

fo×Da/2^{k}=fv×Db/2^{k}, fv/fo=Da/Db [1]

Herein, “fo” is the frequency of the reference frequency signal, “fv” is the frequency of the output signal, “Da” is a frequency setting value (positive integer) of the DDS 11a, “Db” is a frequency setting value (positive integer) of the DDS 11b, and “k” is the bit number of the setting resolution of each of DDSs 11a and 11b (the bit number of the DDS 11a and the bit number of the DDS 11b are the same as each other).

Further, in case of the PLL circuit 1 according to an embodiment of the present invention, as shown in the above-described equation [1], the frequency setting values Da and Db are determined so that the ratio of the frequency (fo) of the reference frequency signal to the frequency (fv) of the output signal is the same as the ratio of the frequency setting value Da of the DDS 11a to the frequency setting value Db of the DDS 11b.

The setting values Da and Db are calculated by substituting the specific numeral values for the above-described equation [1]. For example, according to the PLL circuit 1, in case of outputting the output signal having the 101 Hz frequency (fv=101 Hz) on the basis of the reference frequency signal having the 10 Hz frequency (fo=10 Hz), the setting values Da and Db are determined as follows.

10×(Da/2^{k})=101×(Db/2^{k}), 101/10=Da/Db

Herein, when each of the setting values Da and Db is smaller than 2^{k-1} (Da, Db<2^{k-1}), and the bit number “k” is 10 (k=10-bit), each of the setting values Da and Db is smaller than 512.

The possible combination of the setting values Da and Db will be shown as follows.

Db=20, Da=202

Db=30, Da=303

Db=40, Da=404

Db=50, Da=505

Herein, in order to improve the property of the PLL, the frequency (fr) of the phase reference signal is required to be higher. Therefore, when the setting value “Db” is 50 (Db=50), and the setting value “Da” is 505 (Da=505), the frequency (fr) of the phase reference signal will be the following value.

10×(505/2¹⁰)=101×(50/2¹⁰)=5050/2¹⁰ ≈4.93 Hz

Accordingly, because the PLL circuit can have the structure using the phase reference signal having the same frequency (fr) as the frequency of the phase reference signal used by the PLL circuit 10 using the DDS according to an earlier development, the PLL circuit can output the output signal having the frequency (fv) which has an error for the 10 Hz frequency (fo) (fo=10 Hz) of the optional reference frequency signal, with approximately keeping the C/N (Carrier to Noise) ratio performance. Further, in case the spurious output is generated over the permissible level of the output signal when the setting values are as described above (for example, Db=50, Da=505), it is possible to avoid generating the spurious output without a frequency error in the output signal, for example, if the setting value “Db” is 40 (Db=40) and the setting value “Da” is 404 (Da=404).

According to the above-described embodiment of the present invention, the DDS 11a divides the frequency (fo) of the reference frequency signal, and outputs the phase reference signal having the frequency (fr) to the PD 12. Then, the PD 12 determines the reference phase based on the frequency (fr) of the phase reference signal outputted from the DDS 11a. On the other hand, the DDS 11b changes the signal outputted from the VCO 13 so as to have the frequency corresponding to the frequency set by the DDS 11a, and outputs the dividing signal to the PD 12. Then, the PD 12 detects the phase difference between the above-described phase reference signal and the dividing signal, and outputs the phase difference to the VCO 13. Thereafter, the VCO 13 corrects the phase change on the basis of the detected phase difference, and outputs the output signal having the constant frequency.

Consequently, the setting values of the DDSs 11a and 11b are determined so that the ratio (Da/Db) of the setting value Da to the setting value Db is equal to the ratio (fv/fo) of the frequency of the phase reference signal to the frequency of the dividing signal. As a result, even if each of the setting values Da and Db is an integer, it is possible to output the output signal having the correct frequency (fv) without causing an error in the frequency (fv) of the output signal.

Further, when the setting values of the DDS 11a and 11b are changed, it is possible to optionally change the frequency (fv) of the output signal outputted from the VCO 13, and to more accurately set the frequency (fv) of the output signal according to the high resolution of the DDSs 11a and 11b.

Furthermore, because the combination of the setting values Da and Db can be optionally selected for the frequency (fv) of the output signal, it is possible to avoid generating the spurious output by changing the setting values, without expanding the size of the circuit, causing a frequency error in the output signal, and changing the frequency of the output signal.

Although the present invention has been explained according to the above-described embodiment, it should also be understood that the present invention is not limited to the embodiment and various chanted and modifications may be made to the invention without departing from the gist thereof.

According to the present invention, the following effects will be indicated.

As described above, even if each of the oscillating frequency setting value set by the clock generator and the oscillating frequency setting value set by the divider is an integer, in case the ratio of the oscillating frequency setting value set by the clock generator to the oscillating frequency setting value set by the divider coincides with the ratio of the oscillating frequency of the reference input signal to the oscillating frequency of the output signal, it is possible that the controller outputs the output signal having the correct and constant frequency without including an error.

Further, it is possible to optionally change the oscillating frequency of the output signal outputted from the controller by changing the oscillating frequency setting value set by the clock generator and the oscillating frequency setting value set by the divider. Further, it is possible to set the more accurate oscillating frequency according to the high resolution of the direct digital synthesizer.

Further, because it is possible to optionally select the combination of the oscillating frequency setting values (Da) and (Db) for the frequency (fv) of the output signal, it is possible to avoid generating the spurious output without expanding the size of the circuit and causing the frequency error, by changing the oscillating setting values.

Further, even if the spurious output is generated, it is possible to avoid generating the spurious output without changing the oscillating frequency of the output signal.

The entire disclosure of Japanese Patent Application No. Tokugan 2001-386220 filed on Dec. 19, 2001 including specification, claims, drawings and summary are incorporated herein by reference in its entirety.

What is claimed is:

1. A PLL circuit comprising:
a clock generator for generating and outputting a clock signal having an oscillating frequency, on the basis of a reference input signal;
a phase detector for detecting a phase difference between the clock signal outputted from the clock generator and an output feedback signal, and outputting a phase difference signal;
a controller for controlling an oscillating frequency of an output signal on the basis of the phase difference signal outputted from the phase detector; and
a divider for dividing the oscillating frequency of the output signal outputted from the controller, and outputting a dividing signal having an oscillating frequency corresponding to the oscillating frequency of the clock signal, as the output feedback signal.

2. The PLL circuit as claimed in claim 1, wherein each of the clock generator and the divider comprises a direct digital synthesizer for generating a signal corresponding to an optional oscillating frequency.

3. The PLL circuit as claimed in claim 1, wherein a relationship between a ratio of an oscillating frequency (fo) of the reference input signal inputted to the clock generator to the oscillating frequency (fv) of the output signal outputted from the controller, and a ratio of an oscillating frequency setting value (Da) set by the clock generator to an oscillating frequency setting value (Db) set by the divider, is shown in the following equation [1]:
fv/fo=Da/Db [1].

4. The PLL circuit as claimed in claim 3, wherein the oscillating frequency setting values of the clock generator and the divider are changed with keeping the relationship shown in the equation [1], the clock generator and the divider each of which comprises a direct digital synthesizer for generating a signal corresponding to an optional oscillating frequency, when a spurious output is generated in the output signal.

5. A control method for a PLL circuit comprising:
generating and outputting a clock signal having an oscillating frequency, on the basis of a reference input signal;
detecting a phase difference between the clock signal outputted and an output feedback signal, and outputting a phase difference signal;
controlling an oscillating frequency of an output signal on the basis of the phase difference signal outputted; and
dividing the oscillating frequency of the output signal outputted, and outputting a dividing signal having an oscillating frequency corresponding to the oscillating frequency of the clock signal, as the output feedback signal.

6. The control method as claimed in claim 5, wherein the generating and outputting a clock signal is accomplished by a first direct digital synthesizer for generating a signal corresponding to an optional oscillating frequency, and
the dividing the oscillating frequency of the output signal outputted, and outputting a dividing signal is accomplished by a second direct digital synthesizer for generating a signal corresponding to an optional oscillating frequency.

7. The control method as claimed in claim 6, further comprising: changing an oscillating frequency setting value (Da) set by the first direct digital synthesizer and an oscillating frequency setting value (Db) set by the second direct digital synthesizer with keeping a relationship between a ratio of an oscillating frequency (fo) of the reference input signal to the oscillating frequency (fv) of the output signal and a ratio of the oscillating frequency setting value (Da) to the oscillating frequency setting value (Db), shown in the following equation, when a spurious output is generated in the output signal:
fv/fo=Da/Db.
